(19) United States
(12) Patent Application Publication
(10) Pub. No.: US 2026/0371647 A1
(43) Pub. Date: Nov. 19, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Ching-Wen Hung, Tainan City (TW); Peng-Hsiu Chen, Tainan City (TW); Su-Ming Hsieh, Tainan City (TW); Chun-Hsien Lin, Tainan City (TW)

(73) Assignee: UNITED MICROELECTRONICS CORP., Hsin-Chu City (TW)

(21) Appl. No.: 19/180,111

(22) Filed: Apr. 15, 2025

(30) Foreign Application Priority Data
Mar. 18, 2025 (TW) 114109978

(51) Int. Cl. H10D 30/66; H10D 30/01; H10D 64/27; H10D 64/68

(52) U.S. Cl. CPC H10D 30/668; H10D 30/0297; H10D 64/516; H10D 64/518; H10D 64/693

(57) ABSTRACT

A method for fabricating a semiconductor device includes the steps of first forming a trench in a substrate, forming a gate dielectric layer in the trench, forming a liner on the gate dielectric layer, forming a gate structure on the liner, forming a source electrode on the substrate, and then forming a drain electrode on a backside of the substrate. Preferably, the gate dielectric layer includes a U-shape cross-section and the liner includes a reverse T-shape cross-section.

### BACKGROUND OF THE INVENTION

### 1. Field of the Invention

The invention relates to a semiconductor device and fabrication method thereof, and more particularly to a silicon carbide (SiC) metal oxide semiconductor field effect transistor (MOSFET) and method for fabricating the same.

### 2. Description of the Prior Art

Typical power semiconductor device includes insulated gate bipolar transistors (IGBTs) and metal oxide semiconductor field effect transistor (MOSFET) device, within which silicon carbide (SiC) MOSFET has critical breakdown strength, can operate at much higher temperatures, provide higher current density, and support higher switching frequencies.

Although semiconductor device such as SiC MOSFET has the above-mentioned advantages, the gate oxide of silicon carbide (SiC) MOSFET is especially vulnerable on voltage spiking induced on gate bias during operation and electrostatic discharge (ESD) stress because of thinner gate oxide thickness and lower oxide quality. In conventional approach, additional devices may be added for protecting gate oxide from voltage overshot and ESD stress. However, extra space is usually required for accommodating these devices, which ultimately increases cell pitch of the entire device. Since conventional approach for fabricating SiC MOSFETs still exist numerous problems, how to come up with a novel approach for fabricating SiC MOSFETs to resolve the above issues has become an important task in this field.

### SUMMARY OF THE INVENTION

According to an embodiment of the present invention, a method for fabricating a semiconductor device includes the steps of first forming a trench in a substrate, forming a gate dielectric layer in the trench, forming a liner on the gate dielectric layer, forming a gate structure on the liner, forming a source electrode on the substrate, and then forming a drain electrode on a backside of the substrate. Preferably, the gate dielectric layer includes a U-shape cross-section and the liner includes a reverse T-shape cross-section.

According to another aspect of the present invention, a semiconductor device includes a trench in a substrate, a gate dielectric layer in the trench, a liner on the gate dielectric layer, a gate structure on the liner, a source electrode on the substrate, and a drain electrode on a backside of the substrate.

According to yet another aspect of the present invention, a semiconductor device includes a trench in a substrate, a doped region under the trench, a gate dielectric layer in the trench, a gate structure on the gate dielectric layer, a source electrode on the substrate, and a drain electrode on a backside of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a semiconductor device according to an embodiment of the present invention.

FIGS. 10-14 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

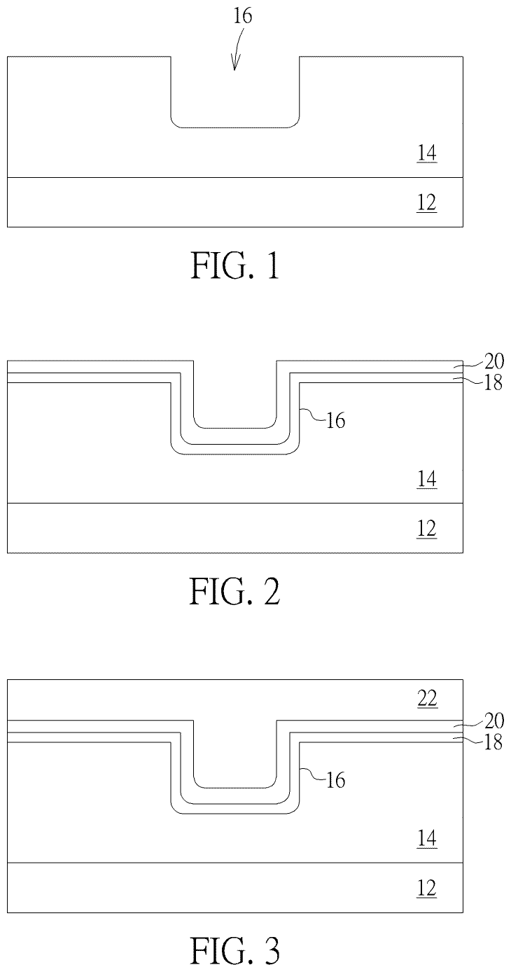

Referring to FIGS. 1-9, FIGS. 1-9 illustrate a method for fabricating a semiconductor device according to an embodiment of the present invention. As shown in FIG. 1, a substrate 12 made of semiconductor material is provided, in which the substrate 12 preferably includes a silicon carbide (SiC) substrate. Nevertheless, according to other embodiment of the present invention, the substrate 12 could also include a silicon substrate, an epitaxial silicon substrate, or even a silicon-on-insulator (SOI) substrate, which are all within the scope of the present invention.

Next, a drift region 14 is formed in the substrate 12, and a photo-etching process is conducted to remove part of the substrate 12 or drift region 14 to form a trench 16, in which the bottom surface of the trench 16 is slightly higher than the bottom surface of the drift region 14. In this embodiment, the drift region 14 preferably includes a N− drift region, but not limited thereto.

Next, as shown in FIG. 2, a gate dielectric layer 18 is formed in the trench 16 and then a liner 20 is formed on the gate dielectric layer 18, in which the gate dielectric layer 18 and the liner 20 could have substantially equal thickness. Preferably, the gate dielectric layer 18 includes silicon oxide and the liner 20 includes silicon nitride (SiN), but not limited thereto.

Next, as shown in FIG. 3, an organic dielectric layer (ODL) 22 is formed in the trench 16, in which the ODL 22 preferably fills the trench 16 completely and covers the surface of the liner 20 adjacent to two sides of the trench 16.

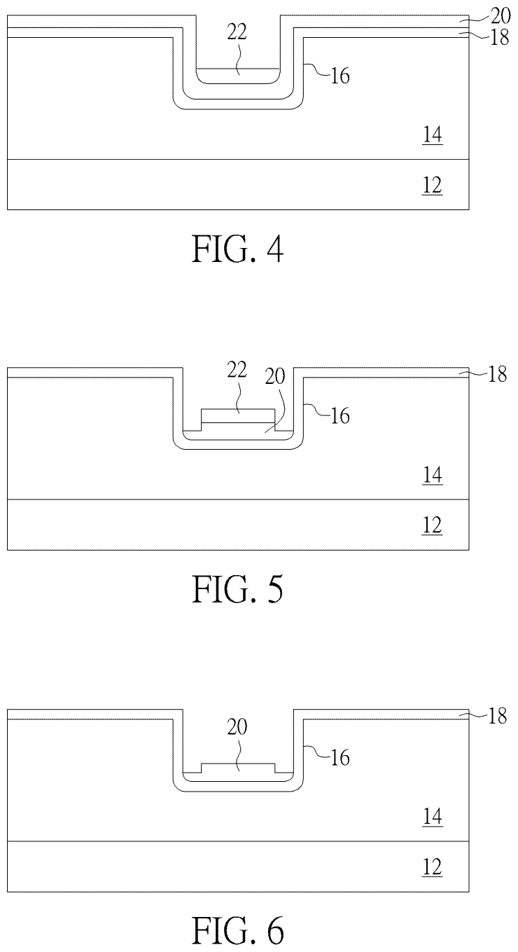

Next, as shown in FIG. 4, an etching back process is conducted to remove part of the ODL 22 within the trench 16 and all the ODL 22 adjacent to two sides of the trench 16 so that the remaining ODL 22 is only disposed on the surface of the liner 22 within the trench 16. Preferably, the top surface of the remaining ODL 22 is lower than the surface of the substrate 12 or drift region 14 adjacent to two sides of the trench 16 or even lower than half of the entire depth of the trench 16, the ODL 22 includes an I-shape cross-section, and the thickness of the remaining ODL 22 could be equal to the thickness of the liner 20 and/or gate dielectric layer 18.

Next, as shown in FIG. 5, an etching process such as a wet etching process could be conducted to remove all the liner 20 adjacent to two sides of the trench 16 and part of the liner 20 adjacent to two sides of the ODL 22 so that the remaining liner 20 is disposed on the gate dielectric layer 18 adjacent to two sides and directly under the ODL 22. Preferably, the remaining liner 20 at this stage includes a reverse T-shape cross-section and sidewalls of the ODL 22 are aligned with sidewalls of the liner 20 underneath.

Next, as shown in FIG. 6, another etching process is conducted to completely remove the ODL 22 and expose the surface of the liner 20.

Next, as shown in FIG. 7, a gate structure 24 is formed in the trench 16. In this embodiment, the formation of the gate structure 24 could be accomplished by first forming a gate material layer (not shown) to fill the trench 16 completely and then using an etching process to remove part of the gate material layer and part of the gate dielectric layer 18 adjacent to two sides of the trench 16 for forming a gate structure 24 or gate electrode made of patterned gate material layer. In this embodiment, the gate material layer or gate structure 24 could include polysilicon or metal, but not limited thereto.

Next, as shown in FIG. 8, a well region 26 is formed in the substrate 12 or drift region 14 adjacent to two sides of the trench 16 or gate structure 24, a first doped region 30 and a second doped region 32 are formed in the well region 26 adjacent to one side such as left side of the trench 16, a third doped region 34 and a fourth doped region 36 are formed in the well region 26 adjacent to another side such as right side of the trench 16, and then an interlayer dielectric (ILD) layer 40 is formed on the substrate 12 to cover the gate structure 24, the gate dielectric layer 18, part of the second doped region 32, and part of the third doped region 34. Preferably, the formation of the ILD layer 40 could be accomplished by first depositing a dielectric layer (not shown) made of oxide on the substrate 12 and then removing part of the dielectric layer through a photo-etching process to form the ILD layer 40.

In this embodiment, the drift region 14 and the well region 26 preferably include different conductive type, the first doped region 30 and the second doped region 32 include different conductive type, and the third doped region 34 and the fourth doped region 36 include different conductive type. For instance, the drift region 14 preferably includes a N− drift region, the well region 26 includes a P-well, the first doped region 30 includes a P+ doped region, the second doped region 32 includes a N+doped region, the third doped region 34 includes a N+ doped region, the fourth doped region 36 includes a P+ doped region, and the ILD layer 40 could include silicon oxide such as tetraethyl orthosilicate (TEOS), but not limited thereto.

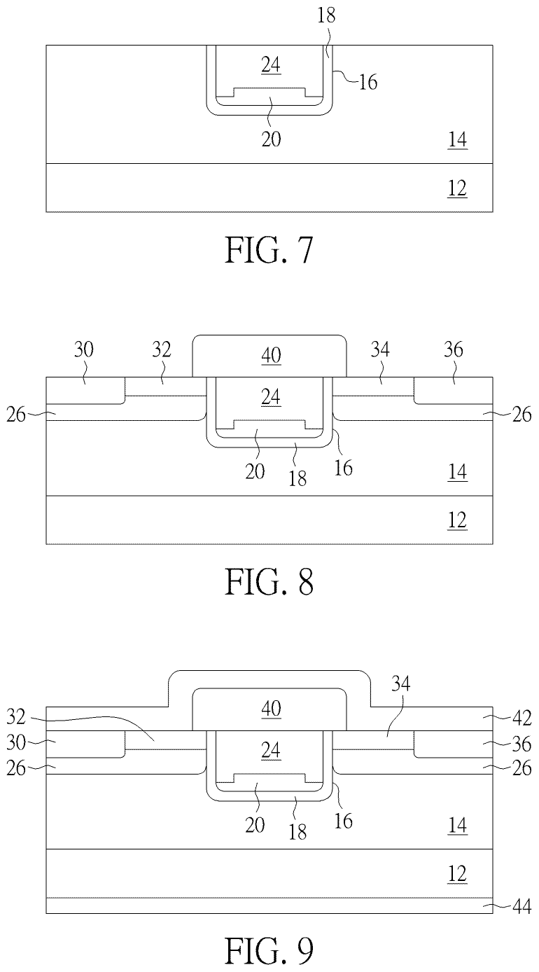

Next, as shown in FIG. 9, a source electrode 42 is formed on the gate structure 24 to cover or overlap the first doped region 30, the second doped region 32, the third doped region 34, and the fourth doped region 36. Preferably, the source electrode 42 could include conductive material or metal material such as aluminum (Al), titanium (Ti), or titanium nitride (TiN). Next, the substrate 12 could be reversed and a deposition process is conducted to form a metal layer on the backside or bottom surface of the substrate 12 serving as a drain electrode 44. In this embodiment, the drain electrode 44 and the source electrode 42 could include same material or different material. For instance, the drain electrode 44 could include conductive material or metal such as Al, Ti, or TiN. This completes the fabrication of a semiconductor device or SiC MOSFET.

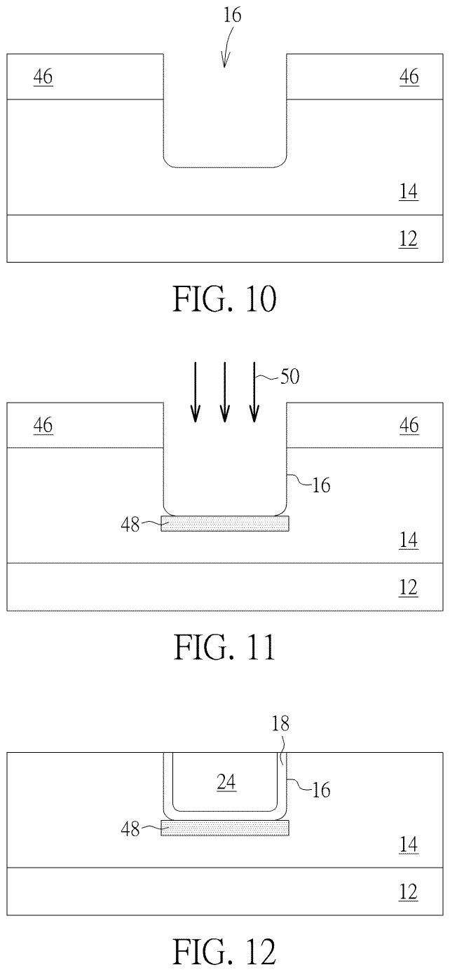

Referring to FIGS. 10-14, FIGS. 10-14 illustrate a method for fabricating a semiconductor device according to an embodiment of the present invention. For simplicity purpose, same elements from the aforementioned embodiment and following embodiment are labeled with same numbering. As shown in FIG. 10, a substrate 12 made of semiconductor material is provided, in which the substrate 12 preferably includes a silicon carbide (SiC) substrate. Nevertheless, according to other embodiment of the present invention, the substrate 12 could also include a silicon substrate, an epitaxial silicon substrate, or even a silicon-on-insulator (SOI) substrate, which are all within the scope of the present invention.

Next, a drift region 14 is formed in the substrate 12, and a photo-etching process is conducted by using a patterned mask 46 as mask to remove part of the substrate 12 or drift region 14 to form a trench 16, in which the bottom surface of the trench 16 is slightly higher than the bottom surface of the drift region 14.

Next, as shown in FIG. 11, an ion implantation process 50 is conducted by using the same patterned mask 46 to inject dopants into the substrate 12 or drift region 14 directly under the trench 16 for forming a doped region 48. Preferably, the drift region 14 and the doped region 48 include dopants with different conductive type. For instance, the drift region 14 in this embodiment includes a N− drift region while the doped region 48 includes a P-type doped region, but not limited thereto.

Next, as shown in FIG. 12, after stripping the patterned mask 48, a gate dielectric layer 18 is formed into the trench 16 and a gate structure 24 is formed on the gate dielectric layer 18 thereafter, in which the gate dielectric layer 18 preferably contacts the doped region 48 in the substrate 12 directly. Similar to the aforementioned embodiment, the gate dielectric layer 18 includes silicon oxide and the gate structure 24 could include polysilicon or metal, but not limited thereto. Moreover, the overall thickness of the doped region 48 could be slightly less than, equal to, or greater than the thickness of the gate dielectric layer 18 and two sidewalls of the doped region 48 could be aligned with or not aligned with two sidewalls of the trench 16 above, which are all within the scope of the present invention.

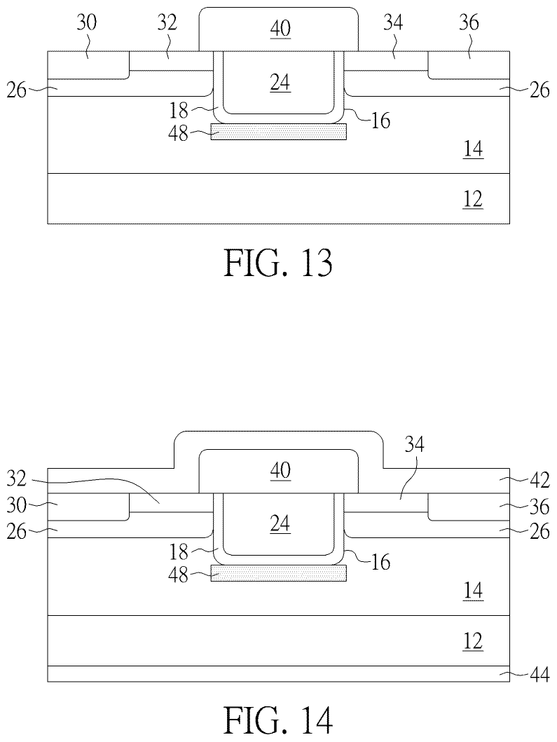

Next, as shown in FIG. 13, a well region 26 is formed in the substrate 12 or drift region 14 adjacent to two sides of the trench 16 or gate structure 24, a first doped region 30 and a second doped region 32 are formed in the well region 26 adjacent to one side such as left side of the trench 16, a third doped region 34 and a fourth doped region 36 are formed in the well region 26 adjacent to another side such as right side of the trench 16, and then an interlayer dielectric (ILD) layer 40 is formed on the substrate 12 to cover the gate structure 24, the gate dielectric layer 18, part of the second doped region 32, and part of the third doped region 34. Preferably, the formation of the ILD layer 40 could be accomplished by first depositing a dielectric layer (not shown) made of oxide on the substrate 12 and then removing part of the dielectric layer through a photo-etching process to form the ILD layer 40.

Similar to the aforementioned embodiment, the drift region 14 and the well region 26 preferably include different conductive type, the first doped region 30 and the second doped region 32 include different conductive type, and the third doped region 34 and the fourth doped region 36 include different conductive type. For instance, the drift region 14 preferably includes a N− drift region, the well region 26 includes a P-well, the first doped region 30 includes a P+ doped region, the second doped region 32 includes a N+ doped region, the third doped region 34 includes a N+ doped region, the fourth doped region 36 includes a P+ doped region, and the ILD layer 40 could include silicon oxide such as tetraethyl orthosilicate (TEOS), but not limited thereto.

Next, as shown in FIG. 14, a source electrode 42 is formed on the gate structure 24 to cover the first doped region 30, the second doped region 32, the third doped region 34, and the fourth doped region 36. Preferably, the source electrode 42 could include conductive material or metal material such as aluminum (Al), titanium (Ti), or titanium nitride (TiN). Next, the substrate 12 could be reversed and a deposition process is conducted to form a metal layer on the backside or bottom surface of the substrate 12 serving as a drain electrode 44. In this embodiment, the drain electrode 44 and the source electrode 42 could include same material or different material. For instance, the drain electrode 44 could include conductive material or metal such as Al, Ti, or TiN. This completes the fabrication of a semiconductor device or SiC MOSFET.

Overall, the present invention discloses a SiC MOSFET having deep trench gate structure and fabrication method thereof, which could be accomplished by first forming a trench in the substrate as revealed in FIGS. 1-9, sequentially forming a gate dielectric layer and liner in the trench, using an ODL 22 to remove part of the liner adjacent to two sides of the trench, and then forming a gate structure in the trench. In another approach, it would also be desirable to follow the embodiment shown in FIGS. 10-14 by forming a trench in the substrate, forming a doped region 48 directly under the trench through an ion implantation process, and then forming a gate dielectric layer and gate structure in the trench afterwards. According to a preferred embodiment of the present invention, either one of the above approach for fabricating a deep trench type gate structure could improve peak electrical field directly under the gate structure thereby increasing density of the device, lowering channel resistance, and improving overall speed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a trench in a substrate;
forming a gate dielectric layer in the trench;
forming a liner on the gate dielectric layer;
forming a gate structure on the liner;
forming a source electrode on the substrate; and
forming a drain electrode on a backside of the substrate.

2. The method of claim 1, further comprising:
forming the gate dielectric layer in the trench and on the substrate adjacent to two sides of the trench;
forming the liner on the gate dielectric layer;
patterning the liner;
forming the gate structure on the liner;
forming a well region adjacent to two sides of the trench;
forming a first doped region and a second doped region adjacent to one side of the trench;
forming a third doped region and a fourth doped region adjacent to another side of the trench;
forming an interlayer dielectric (ILD) layer on the gate structure; and
forming the source electrode on the first doped region, the second doped region, the third doped region, the fourth doped region, and the ILD layer.

3. The method of claim 2, wherein patterning the liner comprises:
forming an organic dielectric layer (ODL) on the liner in the trench; and
removing the liner adjacent to two sides of the ODL.

4. The method of claim 2, wherein the first doped region and the second doped region comprise different conductive type.

5. The method of claim 2, wherein the third doped region and the fourth doped region comprise different conductive type.

6. The method of claim 1, wherein the gate dielectric layer comprises U-shape.

7. The method of claim 1, wherein the liner comprises a reverse T-shape.

8. A semiconductor device, comprising:
a trench in a substrate;
a gate dielectric layer in the trench;
a liner on the gate dielectric layer;
a gate structure on the liner;
a source electrode on the substrate; and
a drain electrode on a backside of the substrate.

9. The semiconductor device of claim 8, further comprising:
a well region adjacent to two sides of the trench;
a first doped region and a second doped region adjacent to one side of the trench;
a third doped region and a fourth doped region adjacent to another side of the trench; and
an interlayer dielectric (ILD) layer on the gate structure.

10. The semiconductor device of claim 9, wherein the source electrode overlaps the first doped region, the second doped region, the third doped region, the fourth doped region, and the ILD layer.

11. The semiconductor device of claim 9, wherein the first doped region and the second doped region comprise different conductive type.

12. The semiconductor device of claim 9, wherein the third doped region and the fourth doped region comprise different conductive type.

13. The semiconductor device of claim 8, wherein the gate dielectric layer comprises U-shape.

14. The semiconductor device of claim 8, wherein the liner comprises a reverse T-shape.

15. A semiconductor device, comprising:
a trench in a substrate;
a doped region under the trench;
a gate dielectric layer in the trench;
a gate structure on the gate dielectric layer;
a source electrode on the substrate; and
a drain electrode on a backside of the substrate.

16. The semiconductor device of claim 15, further comprising:
a drift region under the trench;
a well region adjacent to two sides of the trench;
a first doped region and a second doped region adjacent to one side of the trench;
a third doped region and a fourth doped region adjacent to another side of the trench; and
an interlayer dielectric (ILD) layer on the gate structure.

17. The semiconductor device of claim 16, wherein the drift region and the dope region comprise different conductive type.

18. The semiconductor device of claim 16, wherein the source electrode overlaps the first doped region, the second doped region, the third doped region, the fourth doped region, and the ILD layer.

19. The semiconductor device of claim 16, wherein the first doped region and the second doped region comprise different conductive type.

20. The semiconductor device of claim 16, wherein the third doped region and the fourth doped region comprise different conductive type.
